(19) United States
(12) Patent Application Publication
(10) Pub. No.: US 2025/0226021 A1
(43) Pub. Date: Jul. 10, 2025

(54) EDRAM CELL AND COMPUTE-IN-MEMORY DEVICE

(71) Applicant: UIF (UNIVERSITY INDUSTRY FOUNDATION), YONSEI UNIVERSITY, Seoul (KR)

(72) Inventors: Seong-Ook JUNG, Seoul (KR); Do-Han KIM, Hwaseong-si (KR)

(73) Assignee: UIF (UNIVERSITY INDUSTRY FOUNDATION), YONSEI UNIVERSITY, Seoul (KR)

(21) Appl. No.: 18/963,479

(22) Filed: Nov. 27, 2024

(30) Foreign Application Priority Data
Jan. 10, 2024 (KR) 10-2024-0004338

(51) Int. Cl. G11C 11/406; G11C 11/408; G11C 11/4096

(52) U.S. Cl. CPC G11C 11/40622; G11C 11/4085; G11C 11/4096

(57) ABSTRACT

An eDRAM cell for a CIM according to the present disclosure includes a first transistor which is connected between a read word line and a read bit line and has a gate connected to a storage node; a second transistor which is connected between a write bit line and the storage node and has a gate connected to a write word line; a first capacitor connected between the storage node and a ground; a third transistor which is connected between a local MAC bit line and a fourth transistor and has a gate connected to the storage node; and a fourth transistor which is connected between the third transistor and the ground and has a gate connected to a MAC word line.

### CROSS-REFERENCE TO RELATED APPLICATIONS

This application claims priority to and the benefit of Korean Patent Application No. 10-2024-0004338 filed in the Korean Intellectual Property Office on Jan. 10, 2024, the entire contents of which are incorporated herein by reference.

### BACKGROUND

### Field

The present disclosure relates to an eDRAM cell for a compute-in-memory (CIM) and an eDRAM cell based CIM device.

### Description of the Related Art

In the case of a Von Neumann structure of the related art, a processor and a memory are separated so that data stored in the memory is read by the processor to perform a computation. Therefore, there is a limitation in improving energy efficiency and a computation speed according to data access and transmission. Further, in recent years, in accordance with the development of the artificial neural network technology, multiply-accumulation (MAC) computation needs to be performed on a large scale between input data and a weight in a deep neural network (DNN) so that a technique for improving the energy efficiency and a operation speed is being demanded.

Therefore, a compute-in-memory (CIM, is also referred to as an in-memory compute) which maximizes the efficiency by performing a computation using a memory which stores data has been proposed. In the CIM structure, the memory which stores data does not transmit data to the processor, but directly performs the computation so that the computation is performed with low power and high speed by overcoming the limitation of the existing Von Neumann.

An SRAM is mainly used in the current CIM structure. The SRAM has a fast operating speed, no need for refresh, and compatibility with a general logic process to be used as an embedded memory, such as a cache memory.

The SRAM has various advantages as described above, but generally, each memory cell is implemented with six, or eight or more transistors so that a large cell area is necessary. Therefore, there is a problem in that a memory capacity is limited in a device with a restricted size. When the SRAM is applied to the CIM, the limited memory capacity causes more frequent access to external memory to update weight data, which results in degradation of throughput and energy efficiency.

In order to solve the problem due to the size of the SRAM, in recent years, an CIM structure based on an embedded DRAM (hereinafter, eDRAM), instead of the SRAM, is actively being studied. Since the eDRAM is implemented based on the DRAM structure, the memory cell is manufactured to have a size much smaller than that of the SRAM. Therefore, it has an advantage in that a memory capacitor is relatively larger in the same area. Therefore, various CIM structures which are implemented based on the eDRAM have been proposed and in the existing eDRAM based CIM structure, in the MAC computation, the accumulation computation is performed based on the current.

Due to the characteristic of the e DRAM that data is stored in a floating node, in the eDRAM based CIM, there is a problem in that an operation result value varies because the data is changed due to the cell leakage over time. In order to solve this problem, a refresh operation is periodically performed. However, in the existing eDRAM based CIM structures, the refresh operation and the MAC operation are performed by sharing one port, which results in the reduction of the throughput due to the refresh. That is, the eDRAM based CIM structures which have been proposed for now are simply focused on increasing of the efficiency of the computation, but do not consider the reduction in efficiency due to the refresh.

Further, there are problem in that the eDRAM based CIM structures of the related art requires a separate digital analog converter and a voltage domain for multi-bit computation and a sensing margin is reduced due to the limited voltage range.

FIG. 1 illustrates an example of an eDRAM based CIM structure of the related art (Z. Chen, X et al., “A 65 nm 3T Dynamic Analog RAM-Based Computing-in-Memory Macro and CNN Accelerator with Retention Enhancement, Adaptive Analog Sparsity and 44TOPS/W System Energy Efficiency,” in IEEE Int. Solid-State Circuits Conf. (ISSCC)Dig. Tech. Papers, pp. 240 to 242, February 2021). FIGS. 2 and 3 illustrate a refresh operation and an MAC operation of the eDRAM based CIM structure of FIG. 1, respectively.

Referring to FIGS. 1 to 3, the eDRAM cell is configured by 3T1C including one PMOS transistor, two NMOS transistors, and one capacitor and an analog voltage (0.48 V to 0.9V) corresponding to a 4-bit weight is stored in the storage node (SN) through the DAC. When a pulse width (50 ps to 400 ps) corresponding to a 4-bit input is applied to a read word line RWL through a digital-to-time converter DTC, a discharge current I_{RBL} is generated in a read bit line RBL according to a weight and an input pulse and I_{RBL} is accumulated to output an MAC computation value.

The refresh operation is configured by a read phase and a write phase and an MAC computation path and a read path are the same so that the MAC computation cannot be performed during the refresh operation, which inevitably reduces the throughput. In the DAM phase, a voltage range is limited due to a Vₜₕ drop problem of the PMOS transistor and each column requires a global DAC, which causes an area overhead problem and a limited voltage range. Further, the NMOS transistor which configures the DAC needs to be maintained in a saturation region so that there is a problem in that the input range and the sensing margin are limited.

FIG. 4 illustrates another example of an eDRAM based CIM structure (Sangwoo. Ha, et al., “A 36.2 dB High SNR and PVT/Leakage-robust eDRAM Computing-In-Memory Macro with Segmented BL and Reference Cell Array,” in IEEE Int. Transctionson Circuits and Systems-II (TCAS-II), April. 2022). FIGS. 5 and 6 illustrate a refresh operation and an MAC operation of the eDRAM based CIM structure of FIG. 4, respectively.

Referring to FIGS. 4 to 6, the eDRAM cell is configured by 2T1C including two PMOS transistors and one capacitor and one-bit data is stored in the storage node SN. When a pulse width (50 ps to 400 ps) corresponding to a 4-bit input is input to the read word line through the DCT, a discharge current I_{R}BL is generated in a read bit line RBL according to a weight and an input pulse and V_{RBL} which is stored in the local bit line through I_{RBL} is accumulated by charge-sharing. Here, a bit position of the weight is reflected by adjusting a number of local computing arrays LCA.

The eDRAM based CIM structure also has the same MAC operation path and reading path so that the MAC computation is inevitably performed during the refresh operation, which results in the reduction in the throughput. Further, each row requires a global DTC for the DAC phase so that a large size of transistor needs to be used for a variation tolerance, which causes an area overhead problem. In the MAC phase, the PMOS transistor needs to be maintained in a saturation region so that there is a problem in that the output range and the sensing margin are limited.

### RELATED ART DOCUMENT

### Non-Patent Documents

[1] Z. Chen, X et al., “A 65 nm 3T Dynamic Analog RAM-Based Computing-in-Memory Macro and CNN Accelerator with Retention Enhancement, Adaptive Analog Sparsity and 44TOPS/W System Energy Efficiency,” in IEEE Int. Solid-State Circuits Conf. (ISSCC)Dig. Tech. Papers, pp. 240-242, February 2021.
[2] Sangwoo. Ha, et al., “A 36.2 dB High SNR and PVT/Leakage-robust eDRAM Computing-In-Memory Macro with Segmented BL and Reference Cell Array,” in IEEE Int. Transctionson Circuits and Systems-II (TCAS-II), April. 2022.

### SUMMARY

An object to be achieved by the present disclosure is to provide an eDRAM cell and a CIM device including the same which remove reduction in a throughput generated by the refresh by separating a refresh port and an MAC port and maximize the operation efficiency.

Further, another object to be achieved by the present disclosure is to provide an eDRAM cell and a CIM device including the same which locally dispose only a small sized transistor without a global DAC to minimize the area overhead due to the DAC.

Still another object to be achieved by the present disclosure is to provide an eDRAM cell and a CIM device including the same which generate a full input voltage range using an intrinsic capacitance of a bit line BL to ensure a larger sensing margin.

The technical object to be achieved by the present disclosure is not limited to the above-mentioned technical objects, and other technical objects, which are not mentioned above, can be clearly understood by those skilled in the art from the following descriptions.

In order to achieve the above-described technical object, according to an aspect of the present disclosure, an eDRAM cell for a CIM includes a first transistor which is connected between a read word line and a read bit line and has a gate connected to a storage node; a second transistor which is connected between a write bit line and the storage node and has a gate connected to a write word line; a first capacitor connected between the storage node and a ground; a third transistor which is connected between a local MAC bit line and a fourth transistor and has a gate connected to the storage node; and a fourth transistor which is connected between the third transistor and the ground and has a gate connected to a MAC word line.

A refresh operation is performed by the first transistor through the read word line and the read bit line and an MAC computation is performed by the third transistor and the fourth transistor through the MAC word line and the local MAC bit line.

The read word line and the read bit line and the MAC word line and the local MAC bit line are separated from each other.

The eDRAM cell for a CIM may further include a second capacitor connected between the storage node and a write assist line.

During the refresh operation, the read bit line which is in a charged state to VDD becomes a floating state and VSS is applied to the read word line, and then the second transistor is turned on through the write word line and VSS is applied to the write assist line so that strong “1” or strong “0” is stored in the storage node.

The first transistor, the third transistor, and the fourth transistor are NMOS transistors and the second transistor is a PMOS transistor.

In order to achieve the above-described technical object, according to another aspect of the present disclosure, a compute-in-memory (CIM) device includes a plurality of local computing arrays, each local computing array is configured by a plurality of local computing cells and each local computing cell includes: a cell array configured by a plurality of eDRAM cells which shares a read bit line, a write bit line, and a local MAC bit line; a local peri circuit which reads a weight from the eDRAM cell through the local MAC bit line and stores a multiplication computation result between input data and a weight in the form of a voltage; and a MOM capacitor which supplies the MAC operation result to an accumulation word line using capacitive coupling, the CIM device further includes: a bit line DAC circuit which is provided in every local computing array and generates a multi-bit input voltage using an intrinsic capacitance of a global MAC bit line provided in every local computing array.

The eDRAM cell includes: a first transistor which is connected between a read word line and a read bit line and has a gate connected to a storage node; a second transistor which is connected between a write bit line and the storage node and has a gate connected to a write word line; a first capacitor connected between the storage node and a ground; a third transistor which is connected between a local MAC bit line and a fourth transistor and has a gate connected to the storage node; and a fourth transistor which is connected between the third transistor and the ground and has a gate connected to a MAC word line.

The local peri circuit includes: a fifth transistor which is connected between VDD and the local MAC bit line; a first inverter which has an input connected to the local MAC bit line and an output connected to a gate of the sixth transistor; a sixth transistor which is connected between a coupling node and a ground and has a gate connected to an output of the first inverter; a seventh transistor which is connected between the ground and the coupling node; and an MAC switch which is connected between the global MAC bit line and the coupling node, and the MOM capacitor is connected between the coupling node and the accumulation word line.

The bit line DAC circuit includes: a tri-state inverter which has an input connected to input data and output connected to the global MAC bit line; and a DAC switch which disconnects or connects between the global MAC bit lines.

During the DAC operation of the MAC computation, VCSS is applied to an enable of the tri-state inverter and the MAC switch is in a closed state so that a voltage of the global MAC bit line and a voltage of the coupling node are charged to the VDD or discharged to VSS, according to the input of the tri-state inverter.

During the DAC operation of the MAC computation, after the voltage of the global MAC bit line and the voltage of the coupling node are charged to the VDD or discharged to VSS, the VDD is applied to the enable of the tri-state inverter and all the DAC switches are closed to connect all the global MAC bit lines, so that the charge sharing occurs by an intrinsic capacitance of the global MAC bit line to generate an analog voltage corresponding to a multi-bit input in the global MAC bit line, thereby pre-charging the coupling node with the analog voltage.

During the multiplication operation of the MAC computation, the MAC word line is turned on and the MAC switch is open so that a voltage of the local MAC bit line drops to VSS according to a voltage of the storage node so that the voltage of the coupling node is discharged to VSS or the voltage of the local MAC bit line is maintained at VDD, thereby maintaining the voltage of the coupling line at the analog voltage.

During an accumulation operation of the MAC computation, the accumulation word line makes a floating state and the seventh transistor is turned on to discharge the voltage of the coupling node through the seventh transistor so that a computation result stored in the coupling node is supplied to the accumulation word line by capacitive coupling.

A refresh operation is performed by the first transistor through the read word line and the read bit line and a MAC computation is performed by the third transistor and the fourth transistor through the MAC word line and the local MAC bit line.

The read word line and the read bit line and the MAC word line and the local MAC bit line are separated from each other.

The eDRAM cell further includes a second capacitor connected between the storage node and a write assist line.

During the refresh operation, the read bit line which is in a charged state to VDD becomes a floating state and VSS is applied to the read word line, and then the second transistor is turned on through the write word line and VSS is applied to the write assist line so that strong “1” or strong “0” is stored in the storage node.

The first transistor, the third transistor, and the fourth transistor are NMOS transistors and the second transistor is a PMOS transistor.

According to the present disclosure, the refresh port and the MAC port are separated so that the MAC computation is possible even during the refresh operation, thereby increasing a throughput and maximizing an operation efficiency.

Further, according to the present disclosure, a multi-bit input voltage is generated without a separate global DAC, thereby minimizing an area overhead due to the DAC.

Further, according to the present disclosure, a full input voltage range is generated using an intrinsic capacitance of the bit line BL, thereby ensuring a larger sensing margin.

Effects of the present disclosure are not limited to the above-mentioned effects, and other effects, which are not mentioned above, can be clearly understood by those skilled in the art from the following descriptions.

### BRIEF DESCRIPTION OF THE DRAWINGS

FIG. 1 is an example of an eDRAM based CIM structure of the related art;

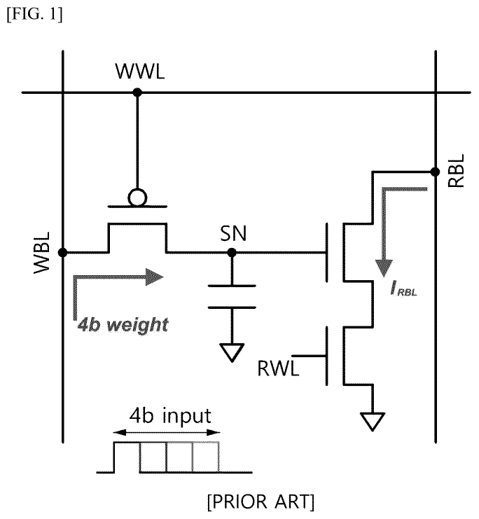

FIG. 2 is a refresh operation of an eDRAM based CIM structure of FIG. 1;

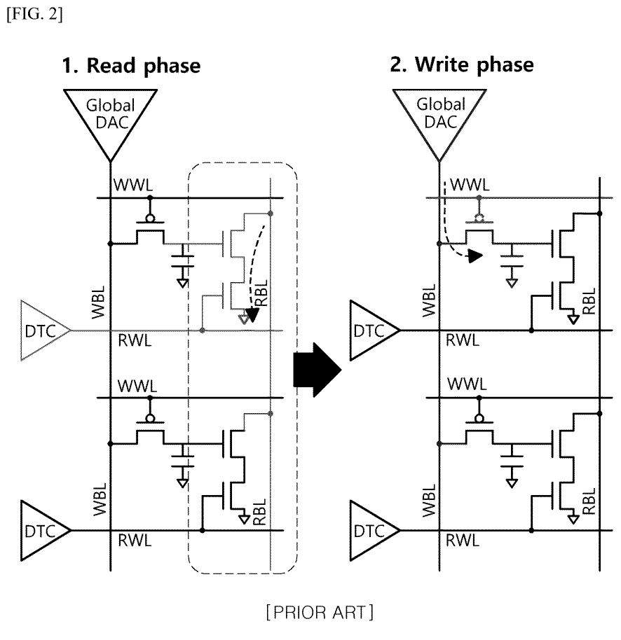

FIG. 3 is an MAC operation of an eDRAM based CIM structure of FIG. 1;

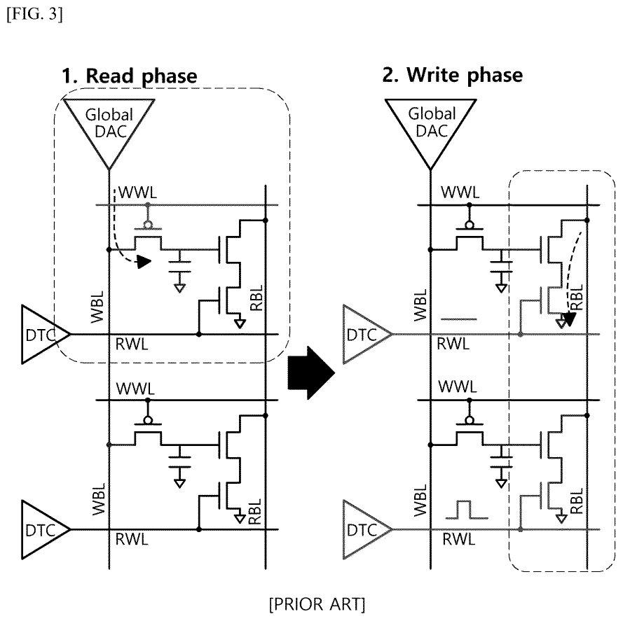

FIG. 4 is another example of an eDRAM based CIM structure of the related art;

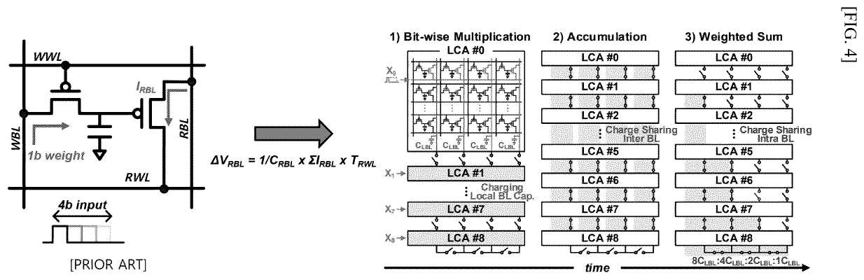

FIG. 5 is a refresh operation of an eDRAM based CIM structure of FIG. 4;

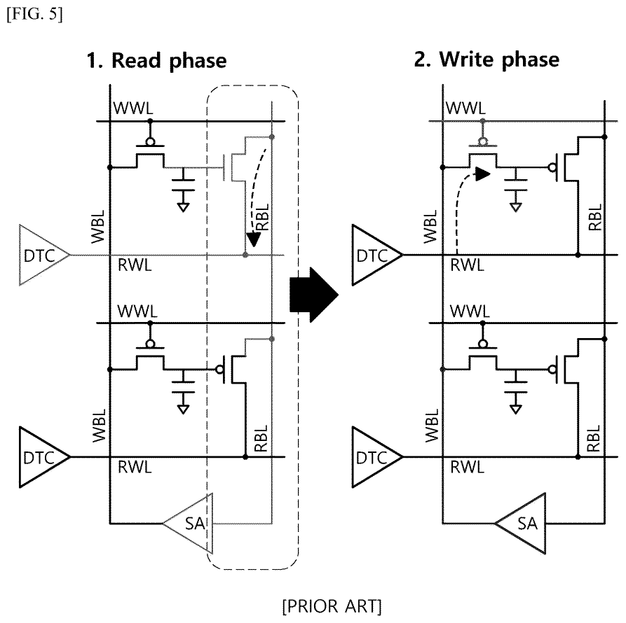

FIG. 6 is an MAC operation of an eDRAM based CIM structure of FIG. 4;

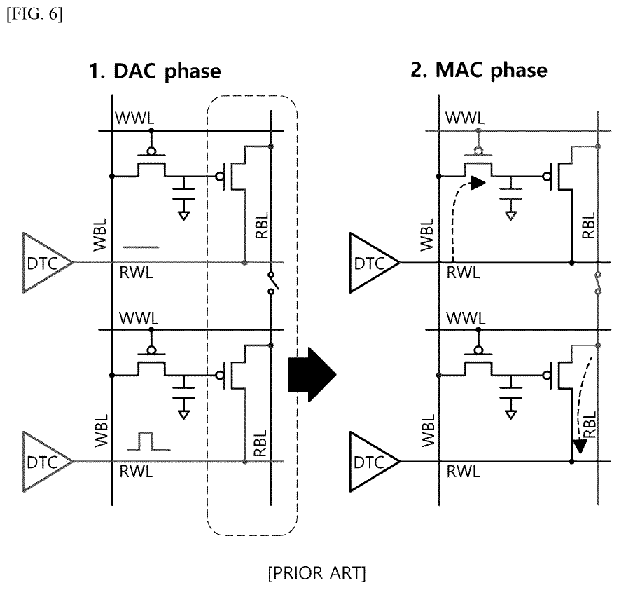

FIG. 7 is a structure of an eDRAM cell and an eDRAM based CIM device according to an exemplary embodiment of the present disclosure;

FIG. 8 illustrates a refresh operation of an eDRAM cell according to an exemplary embodiment of the present disclosure;

FIG. 9 illustrates an initialization operation for an MAC computation of an eDRAM based CIM device according to an exemplary embodiment of the present disclosure;

FIG. 10 is a timing chart according to an initialization operation of FIG. 9;

FIG. 11 illustrates a first step of a DAC operation of an eDRAM based CIM device according to an exemplary embodiment of the present disclosure;

FIG. 12 illustrates a timing chart of a first step of a DAC operation of FIG. 11;

FIG. 13 illustrates a second step of a DAC operation of an eDRAM based CIM device according to an exemplary embodiment of the present disclosure;

FIG. 14 illustrates a timing chart of a second step of a DAC operation of FIG. 13;

FIG. 15 illustrates an operation when data of a storage node SN is 1, in a multiplication operation of an eDRAM based CIM device according to an exemplary embodiment of the present disclosure;

FIG. 16 is a timing chart according to a multiplication operation of FIG. 15;

FIG. 17 illustrates an operation when data of a storage node SN is 0, in a multiplication operation of an eDRAM based CIM device according to an exemplary embodiment of the present disclosure;

FIG. 18 is a timing chart according to a multiplication operation of FIG. 17;

FIG. 19 illustrates an accumulation operation of an eDRAM based CIM device according to an exemplary embodiment of the present disclosure; and

FIG. 20 is a timing chart according to an accumulation operation of FIG. 19.

### DETAILED DESCRIPTION OF THE EMBODIMENT

Hereinafter, exemplary embodiments of the present disclosure will be described in detail with reference to the drawings. Substantially same components in the following description and the accompanying drawings may be denoted by the same reference numerals so that a redundant description will be omitted. Further, in the description of the exemplary embodiment, if it is considered that specific description of related known configuration or function may cloud the gist of the present disclosure, the detailed description thereof will be omitted.

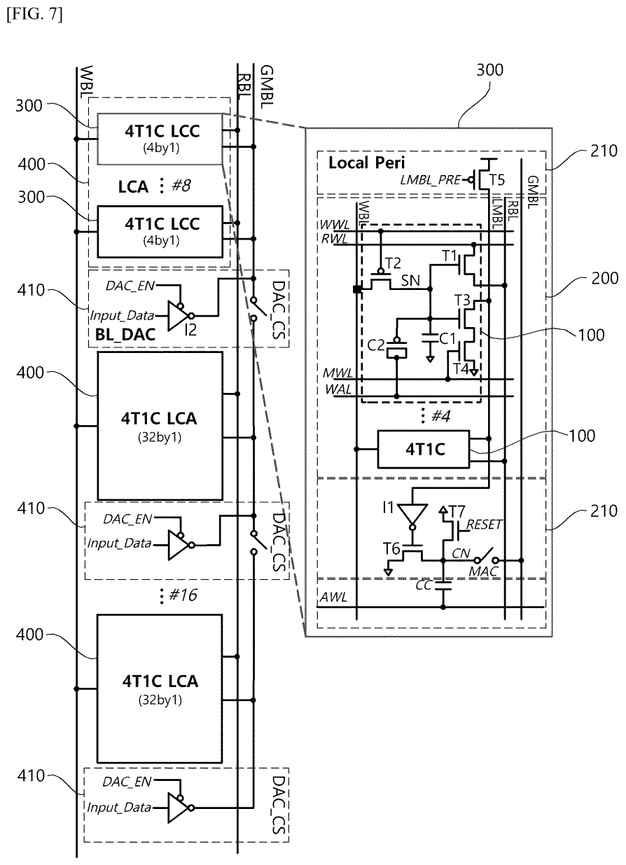

FIG. 7 is a structure of an eDRAM cell and an eDRAM based CIM device according to an exemplary embodiment of the present disclosure.

An eDRAM based CIM device includes an eDRAM cell 100. The eDRAM cell 100 is configured with a 4T1C structure including one PMOS transistor T2, three NMOS transistors T1, T3, and T4, and a capacitor C1.

The first transistor T1 is connected between a read word line RWL and a read bit line RBL and a gate is connected to a storage node SN. The first transistor T1 may be an NMOS transistor.

The second transistor T2 is connected between a write bit line WBL and the storage node SN and a gate is connected to a write word line WWL. The second transistor T2 may be a PMOS transistor.

The first capacitor C1 is provided to store a weight and is connected between the storage node SN and a ground.

The third transistor T3 is connected between a local MAC bit line LMBL and a fourth transistor T4 and a gate is connected to the storage node SN.

The fourth transistor T4 is connected between the third transistor T3 and the ground and a gate is connected to the MAC word line MW).

The second capacitor C2 is connected between the storage node SN and a write assist line WAL. The second capacitor C2 serves to make a voltage of the first capacitor C1 down and is implemented as a MOS capacitor.

The first transistor T1 refreshes by a reading/writing operation. That is, the refresh operation is performed by the first transistor T1 through the read word line RWL and the read bit line RBL.

The third and fourth transistors T3 and T4 serve to read for the MAC computation. That is, the MAC computation is performed by the third and fourth transistors T3 and T4 through the local MAC bit line LMBL and the MAC word line MWL.

A plurality of eDRAM cells 100 configures a cell array 200. The cell array 200 is configured by four eDRAM cells 100 which share the read bit line RBL, the write bit line WBL, and the local MAC bit line LMBL. The cell array 200 serves to store the weight.

The local computing cell (LCC) 300 includes a cell array 200, a local peri circuit 210, and a metal-oxide-metal (MOM) capacitor CC.

The local peri circuit 210 is configured by switches to implement the MAC operation. The local peri circuit 210 reads a weight from the eDRAM cell 100 through the local MAC bit line LMBL to use the weight for the MAC operation and stores a multiplication computation result between multi-bit (for example, 4-bit) input data and 1-bit weight in the coupling node CN in the form of a voltage.

The local peri circuit 210 includes a fifth transistor T5, a first inverter I1, a sixth transistor T6, a seventh transistor T7, and an MAC switch MAC.

The fifth transistor T5 is connected between the VDD and the local MAC bit line LMBL and a gate is connected to a LMBL_PRE signal. The fifth transistor T5 may be a PMOS transistor.

An input of the first inverter I1 is connected to the local MAC bit line LMBL and an output is connected to a gate of the sixth transistor T6.

The sixth transistor T6 is connected between the coupling node CN and the ground and the gate is connected to the output of the first inverter II. The sixth transistor T6 may be an NMOS transistor.

The seventh transistor T7 is connected between the ground and the coupling node CN and a gate is connected to a RESET signal. The seventh transistor T7 may be an NMOS transistor.

The MAC switch MAC is connected between a global MAC bit line GMBL and the coupling node CN.

The MOM capacitor CC is a capacitor formed by laminating a metal on the local peri circuit 210 and reflects the MAC operation result on an accumulated word line AWL using capacitive coupling. The MON capacitor CC is connected between the coupling node CN and the accumulated word line AWL.

A plurality of local computing cells 300 configures a local computing array (LCA) 400. The local computing array 400 is configured by eight local computing cells 300 which share the write bit line WBL, the read bit line RBL, and the global MAC bit line GMBL.

The eDRAM based CIM device includes a plurality of local computing arrays 400 according to a number of bits of the input data. A bit position of the multi-bit input data may be reflected by adjusting a number of local computing arrays 400. For example, when the input data is 4 bits, the eDRAM based CIM device includes 16 local computing arrays 400.

The bit line DAC circuit (BL_DAC) 410 is provided in every local computing array 400. The bit line DAC circuit 410 generates a multi-bit (for example, 4-bit) input voltage using an intrinsic capacitance of the 16 global MAC bit lines GMBL without an additional capacitor.

The bit line DAC circuit (BL_DAC) 410 includes a tri-state inverter I2 and the DAC switch DAC_CS.

An input of the tri-state inverter I1 is connected to input data and an output is connected to the global MAC bi line GMBL and an enable is connected to a DAC_EN signal. The tri-state inverter I2 reflects one-bit, among 4-bit digital input data, to the global MAC bit line GMBL.

The DAC switch DAC_CS blocks or connects between the global MAC bit lines GMBL. The DAC switch DAC_CS connects between the global MAC bit lines GMBL to allow 16 global MAC bit lines GMBL to share charge to generate an input data corresponding to 4 bits.

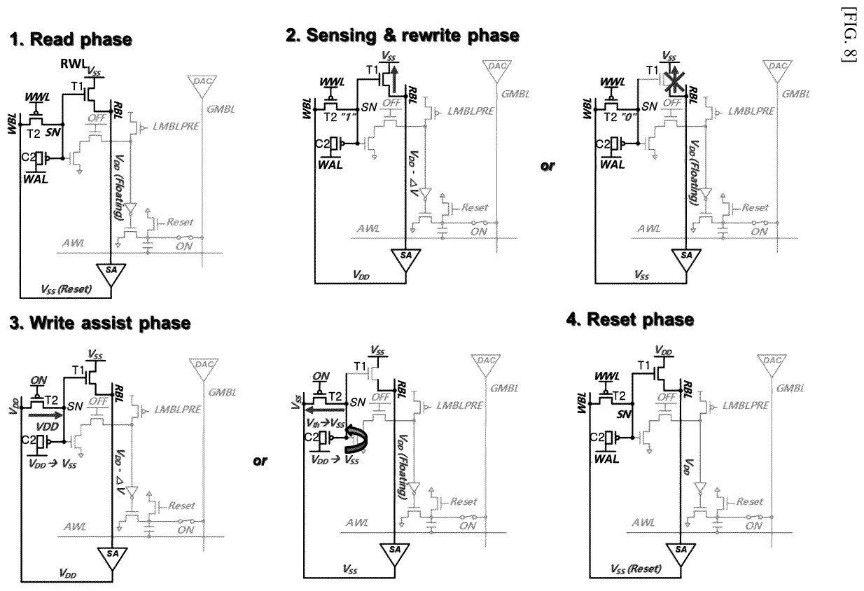

FIG. 8 illustrates a refresh operation of an eDRAM cell according to an exemplary embodiment of the present disclosure;

The read bit line RBL which is in a charged state to VDD is floated, and then VSS is applied to the read word line RWL. When data stored in the storage node SN is “1”, the first transistor T1 is turned on so that charges are discharged from the read bit line RBL to the read word line RWL. When data stored in the storage node SN is “0”, the first transistor T1 is turned off so that charges of the read bit line RBL are not charged, but are maintained. When the read bit line RBL is sensed by a sense amplifier SA, if the data is “1”, an output from the sense amplifier SA drives the write bit line WBL with VDD again and if the data is “0”, an output from the sense amplifier SA drives the write bit line WBL with VSS again. In this state, when the second transistor T2 is turned on through the write word line WWL, if the data is “1”, the write bit line WBL is driven with VDD so that strong “1” is stored in the storage node SN. If the data is “0”, the write bit line WBL is driven with VSS, but strong “0” is not stored in the storage node SN due to the second transistor T2 (PMOS), but the voltage slightly rises by Vth. At this time, when the voltage of the write assist line WAL, drops from VDD to VSS, the voltage of the storage node SN is lowered due to the coupling so that strong “0” is stored.

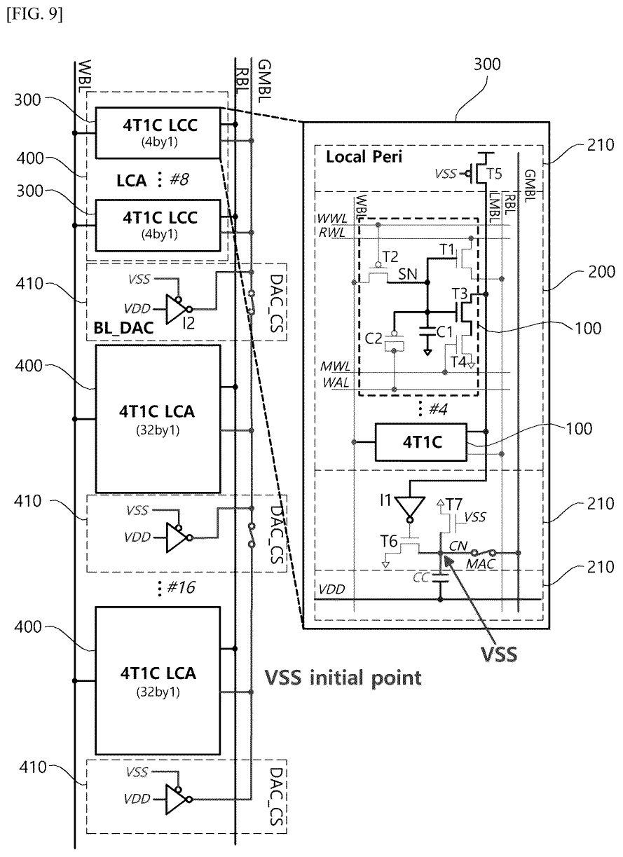

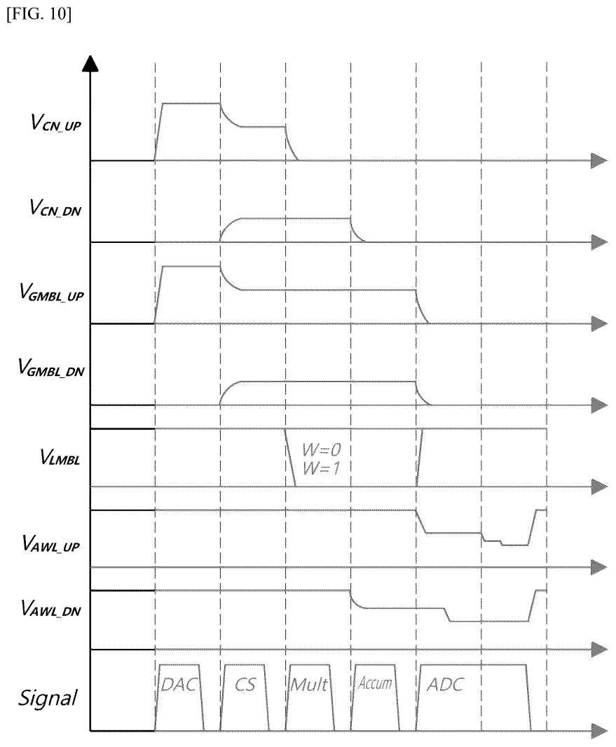

FIG. 9 illustrates an initialization operation for an MAC computation of an eDRAM based CIM device according to an exemplary embodiment of the present disclosure and FIG. 10 is a timing chart according to an initialization operation of FIG. 9;

VSS is applied to the gate of the fifth transistor T5 to initialize the voltage V_{LMBL} of the local MAC bit line to VDD. A voltage V_{AWL} of the accumulated word line AWL is initialized to VDD.

VSS and VDD are applied to the enable and the input of the tri-state inverter I2 so that an output of the tri-state inverter I2 becomes VSS and the DAC switch DAC_CS and the MAC switch MAC are closed so that the voltage V_{GMBL} of the global MAC bit line GMBL and the voltage V_{CN} of the coupling node are initialized to VSS.

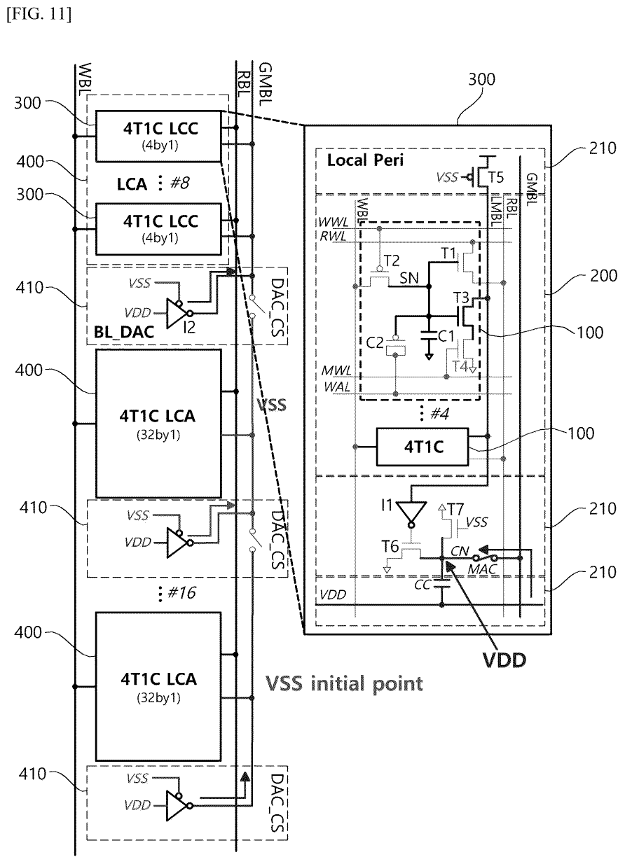

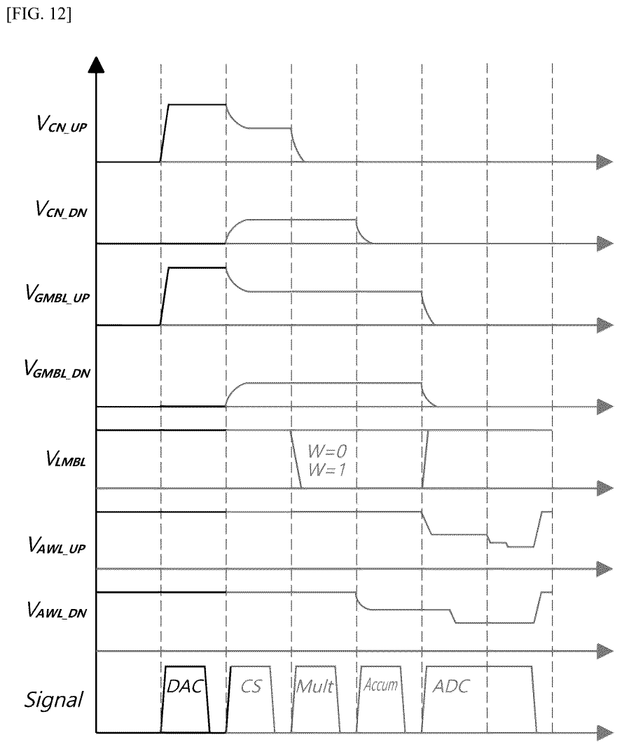

FIG. 11 illustrates a first step of a DAC operation of an eDRAM based CIM device according to an exemplary embodiment of the present disclosure and FIG. 12 illustrates a timing chart of a first step of a DAC operation of FIG. 11.

In FIG. 11, it is illustrated that input data of a first local computing array 400 is 0, that is, VSS is input to an input of the tri-state inverter I2 of the first local computing array 400. When VSS is applied to the enable of the tri-state inverter I2 and VSS is applied to the input of the tri-state inverter I2, a voltage V_{GMBL} of the global MAC bit line GMBL is charged to VDD. Further, the voltage V_{CN} of the coupling node CN is also charged to VDD by the closed MAC switch MAC. When the input data is 1, that is, VDD is applied to the input of the tri-state inverter I2, the voltage V_{GMBL} of the global MAC bit line GMBL is discharged to VSS and the voltage V_{CN} of the coupling node CN is also discharged to VSS. The voltage V_{LMBL} of the local MAC bit line LMBL and the voltage V_{AWL} of the accumulated word line AWL are maintained at VDD.

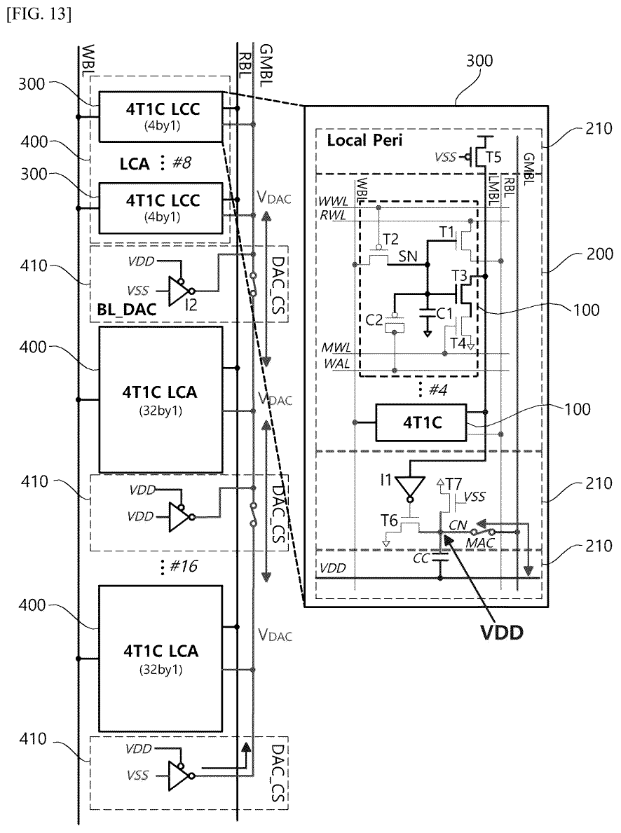

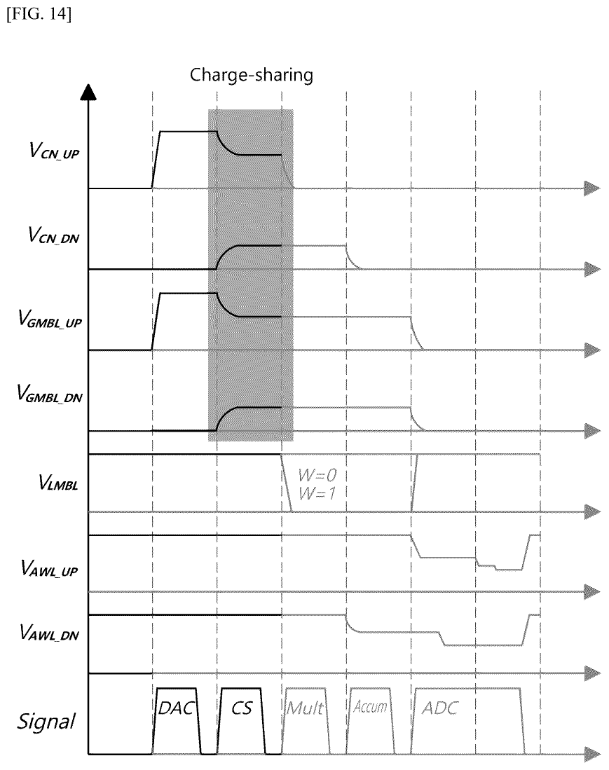

FIG. 13 illustrates a second step of a DAC operation of an eDRAM based CIM device according to an exemplary embodiment of the present disclosure and FIG. 14 illustrates a timing chart of a second step of a DAC operation of FIG. 13.

VDD is applied to the enable of the tri-state inverter I2 to turn off the tri-state inverter I2. When all the DAC switches DAC_CS are closed to connect all the global MAC bit lines GMBL, charge-sharing is caused by the intrinsic capacitance of the global MAC bit line GMBL so that a voltage of V_{GMBL} is an analog voltage V_{DAC} corresponding to 4-bit input data. Accordingly, the voltage V_{CN} of the coupling node CN is precharged to the analog voltage V_{DAC} corresponding to 4-bit input data.

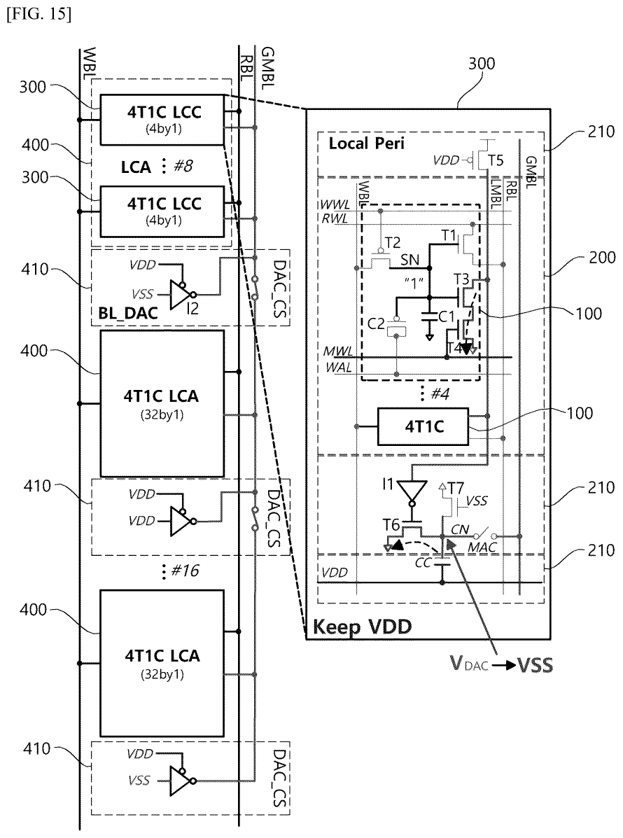

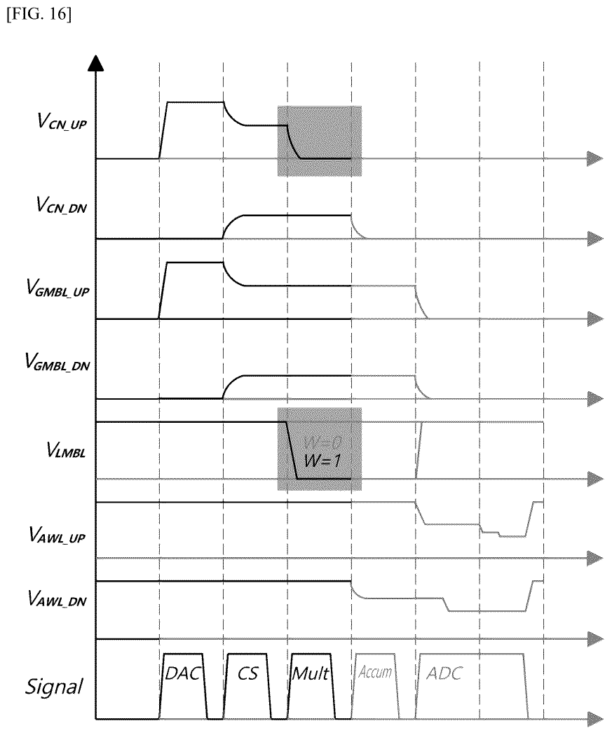

FIG. 15 illustrates an operation when data of a storage node SN is 1 (a weight is 0), in a multiplication operation of an eDRAM based CIM device according to an exemplary embodiment of the present disclosure and FIG. 16 is a timing chart according to a multiplication operation of FIG. 15;

In the multiplication operation, the MAC word line MWL is turned on and the MAC switch MAC which connects the global MAC bit line GMBL and the MOM capacitor CC is turned on.

The voltage of the storage node SN is VDD so that the first transistor T1 is turned on and the local MAC bit line LMBL is charged to VDD so that if the MAC word line MWL is turned on, the fourth transistor T4 is on to drop the voltage V_{LMBL} of the local MAC bit line LMBL to VSS. Accordingly, an output of the first inverter I1 becomes VDD to turn on the sixth transistor T6 so that the voltage V_{CN} (a voltage of the coupling node CN) of the MOM capacitor CC is discharged from V_{DAC} to VSS. V_{GMBL} is maintained to VDAC and V_{AWL} is maintained to VDD.

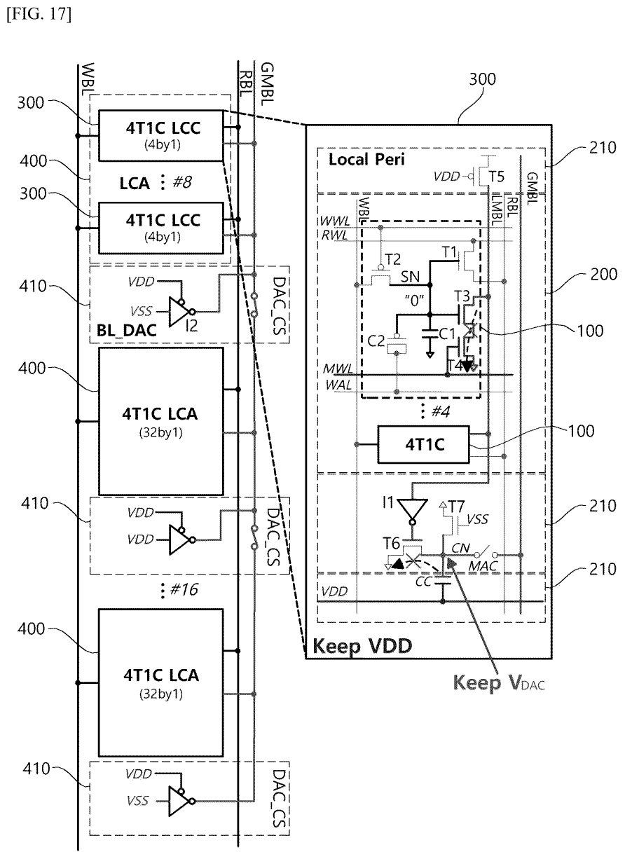

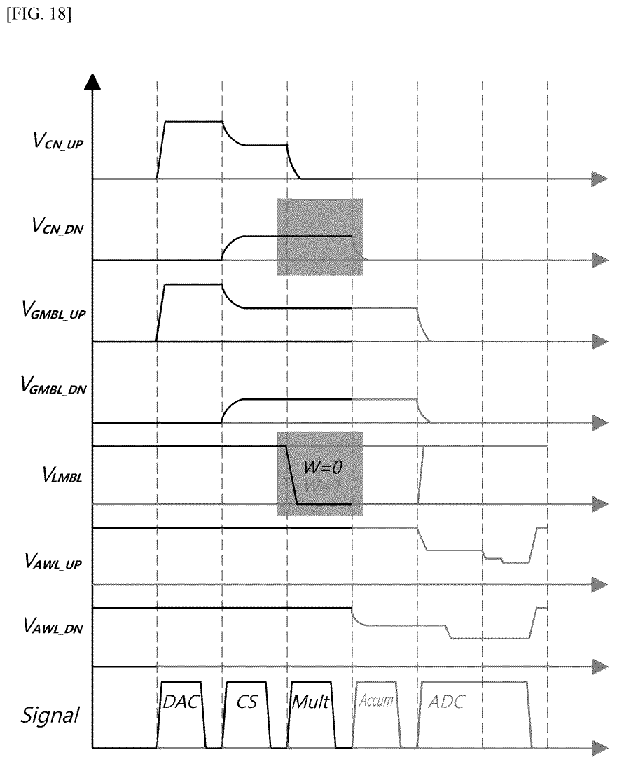

FIG. 17 illustrates an operation when data of a storage node SN is 0 (a weight is 1), in a multiplication operation of an eDRAM based CIM device according to an exemplary embodiment of the present disclosure and FIG. 18 is a timing chart according to a multiplication operation of FIG. 17.

Since the voltage of the storage node SN is VSS, the first transistor T1 is turned off so that the voltage V_{LMBL} of the local MAC bit line LMBL is maintained to VDD. Accordingly, an output of the first inverter I1 becomes VSS to turn off the sixth transistor T6 so that the voltage V_{CN} (the voltage of the coupling node CN) of the MOM capacitor CC is maintained at V_{DAC}.

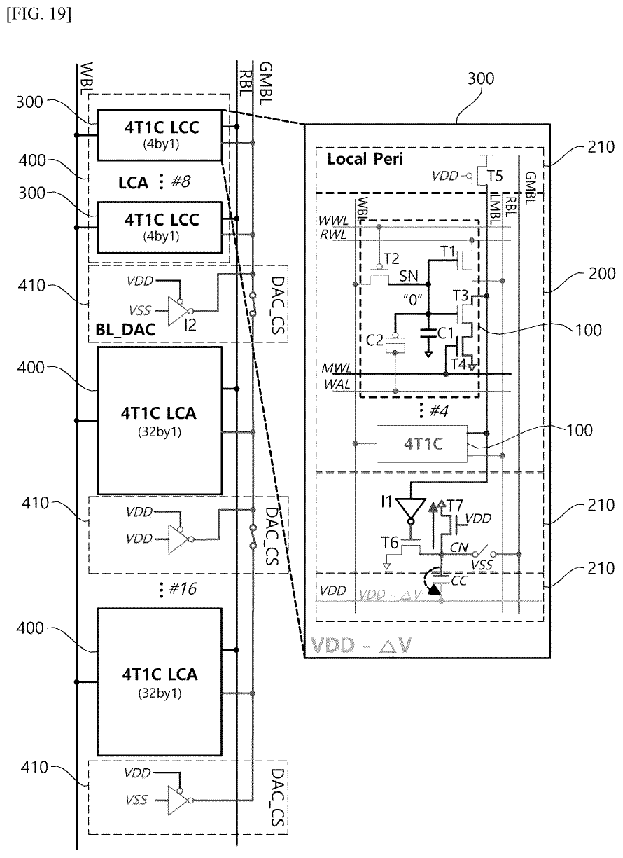

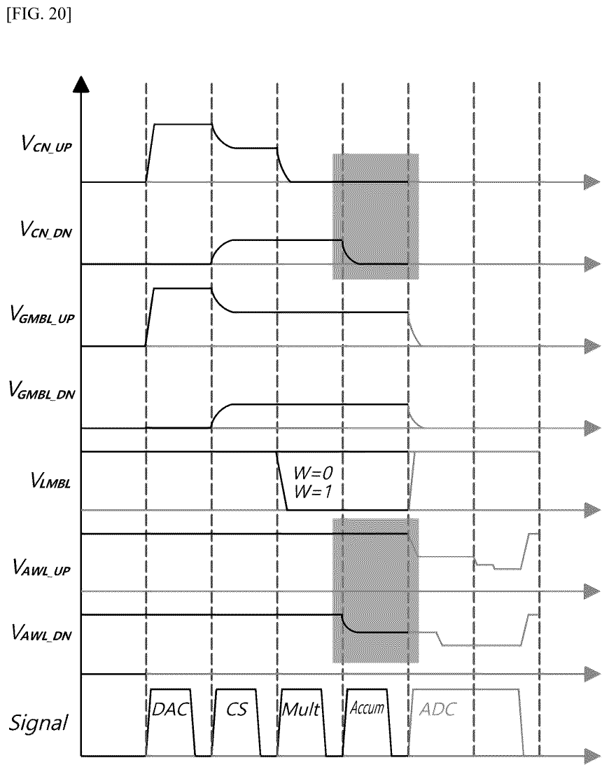

FIG. 19 illustrates an accumulation operation of an eDRAM based CIM device according to an exemplary embodiment of the present disclosure and FIG. 20 is a timing chart according to an accumulation operation of FIG. 19.

Previously, the accumulation word line AWL is driven with VDD, but in the accumulation operation, the VDD driving of the accumulation word line AWL is disconnected to be floated. When the seventh transistor T7 is turned on to discharge the voltage V_{CN} of the coupling node CN through the seventh transistor T7, a computation result stored in V_{CN} is transferred to the accumulation word line AWL by the capacitive coupling. When the data of the storage node SN is 1 (a weight 0), V_{CN} is maintained at VSS and at this time, the voltage V_{AWL} of the accumulation word line AWL is maintained at VDD. When the data of the storage node SN is 0 (a weight 1), the voltage V_{CN} drops from V_{DAC} to VSS and at this time, the voltage V_{AWL} of the accumulation word line AWL drops from VDD to VDD-ΔV. When the voltage V_{AWL} of the accumulation word line AWL is accumulated in the row direction, an analog voltage corresponding to the accumulation computation result is obtained.

According to the present disclosure, the refresh port and the MAC port are separated so that the MAC computation is possible even during the refresh operation, thereby increasing a throughput and maximizing an operation efficiency. Further, a multi-bit input voltage is generated without a separate global DAC, thereby minimizing an area overhead due to the DAC. Further, a full range of input voltage range is generated using an intrinsic capacitance of the global MAC bit line GMBL, thereby ensuring a larger sensing margin.

It will be appreciated that various exemplary embodiments of the present invention have been described herein for purposes of illustration, and that various modifications, changes, and substitutions may be made by those skilled in the art without departing from the scope and spirit of the present invention. Therefore, the exemplary embodiments of the present disclosure are provided for illustrative purposes only but not intended to limit the technical concept of the present disclosure. The scope of the technical concept of the present disclosure is not limited thereto. The protection scope of the present invention should be interpreted based on the following appended claims and it should be appreciated that all technical spirits included within a range equivalent thereto are included in the protection scope of the present invention.

What is claimed is:

1. An eDRAM cell for a CIM, comprising:
a first transistor which is connected between a read word line and a read bit line and has a gate connected to a storage node;
a second transistor which is connected between a write bit line and the storage node and has a gate connected to a write word line;
a first capacitor connected between the storage node and a ground;
a third transistor which is connected between a local MAC bit line and a fourth transistor and has a gate connected to the storage node; and
a fourth transistor which is connected between the third transistor and the ground and has a gate connected to a MAC word line.

2. The eDRAM cell for a CIM according to claim 1, wherein a refresh operation is performed by the first transistor through the read word line and the read bit line and an MAC computation is performed by the third transistor and the fourth transistor through the MAC word line and the local MAC bit line.

3. The eDRAM cell for a CIM according to claim 2, wherein the read word line and the read bit line and the MAC word line and the local MAC bit line are separated from each other.

4. The eDRAM cell for a CIM according to claim 2, further comprising:
a second capacitor connected between the storage node and a write assist line.

5. The eDRAM cell for a CIM according to claim 4, wherein during the refresh operation, the read bit line which is in a charged state to VDD becomes a floating state and VSS is applied to the read word line, and then the second transistor is turned on through the write word line and VSS is applied to the write assist line so that strong “1” or strong “0” is stored in the storage node.

6. The eDRAM cell for a CIM according to claim 1, wherein the first transistor, the third transistor, and the fourth transistor are NMOS transistors and the second transistor is a PMOS transistor.

7. A compute-in-memory (CIM) device, comprising:
a plurality of local computing arrays,
wherein each local computing array is configured by a plurality of local computing cells and
each local computing cell includes:
a cell array configured by a plurality of eDRAM cells which shares a read bit line, a write bit line, and a local MAC bit line;
a local peri circuit which reads a weight from the eDRAM cell through the local MAC bit line and stores a multiplication computation result between input data and a weight in the form of a voltage; and
a MOM capacitor which supplies the MAC operation result to an accumulation word line using capacitive coupling,
the CIM device further includes a bit line DAC circuit which is provided in every local computing array and generates a multi-bit input voltage using an intrinsic capacitance of a global MAC bit line provided in every local computing array.

8. The CIM device according to claim 7, wherein the eDRAM cell includes:
a first transistor which is connected between a read word line and a read bit line and has a gate connected to a storage node;
a second transistor which is connected between a write bit line and the storage node and has a gate connected to a write word line;
a first capacitor connected between the storage node and a ground;
a third transistor which is connected between a local MAC bit line and a fourth transistor and has a gate connected to the storage node; and
a fourth transistor which is connected between the third transistor and the ground and has a gate connected to a MAC word line.

9. The CIM device according to claim 8, wherein the local peri circuit includes:
a fifth transistor which is connected between VDD and the local MAC bit line;
a first inverter which has an input connected to the local MAC bit line and an output connected to a gate of the sixth transistor;
a sixth transistor which is connected between a coupling node and a ground and has a gate connected to an output of the first inverter;
a seventh transistor which is connected between the ground and the coupling node; and
an MAC switch which is connected between the global MAC bit line and the coupling node, and
the MOM capacitor is connected between the coupling node and the accumulation word line.

10. The CIM device according to claim 9, wherein the bit line DAC circuit includes:
a tri-state inverter which has an input connected to input data and output connected to the global MAC bit line; and
a DAC switch which disconnects or connects between the global MAC bit lines.

11. The CIM device according to claim 10, wherein during the DAC operation of the MAC computation, VCSS is applied to an enable of the tri-state inverter and the MAC switch is in a closed state so that a voltage of the global MAC bit line and a voltage of the coupling node are charged to the VDD or discharged to VSS, according to the input of the tri-state inverter.

12. The CIM device according to claim 11, wherein during the DAC operation of the MAC computation, after the voltage of the global MAC bit line and the voltage of the coupling node are charged to the VDD or discharged to VSS, the VDD is applied to the enable of the tri-state inverter and all the DAC switches are closed to connect all the global MAC bit lines, so that the charge sharing occurs by an intrinsic capacitance of the global MAC bit line to generate an analog voltage corresponding to a multi-bit input in the global MAC bit line, thereby pre-charging the coupling node with the analog voltage.

13. The CIM device according to claim 12, wherein during a multiplication operation of the MAC computation, the MAC word line is turned on and the MAC switch is open so that a voltage of the local MAC bit line drops to VSS according to a voltage of the storage node so that the voltage of the coupling node is discharged to VSS or the voltage of the local MAC bit line is maintained at VDD, thereby maintaining the voltage of the coupling line at the analog voltage.

14. The CIM device according to claim 13, wherein during an accumulation operation of the MAC computation, the accumulation word line makes a floating state and the seventh transistor is turned on to discharge the voltage of the coupling node through the seventh transistor so that a computation result stored in the coupling node is supplied to the accumulation word line by capacitive coupling.

15. The CIM device according to claim 8, wherein a refresh operation is performed by the first transistor through the read word line and the read bit line and a MAC computation is performed by the third transistor and the fourth transistor through the MAC word line and the local MAC bit line.

16. The CIM device according to claim 15, wherein the read word line and the read bit line and the MAC word line and the local MAC bit line are separated from each other.

17. The CIM device according to claim 15, further comprising:
a second capacitor connected between the storage node and a write assist line.

18. The CIM device according to claim 17, wherein during the refresh operation, the read bit line which is in a charged state to VDD becomes a floating state and VSS is applied to the read word line, and then the second transistor is turned on through the write word line and VSS is applied to the write assist line so that strong “1” or strong “0” is stored in the storage node.

19. The CIM device according to claim 8, wherein the first transistor, the third transistor, and the fourth transistor are NMOS transistors and the second transistor is a PMOS transistor.
